(19) United States
(12) Patent Application Publication
(10) Pub. No.: US 2007/0181916 A1
(43) Pub. Date: Aug. 9, 2007

(54) Method of manufacturing flash memory device

(75) Inventors: In No Lee, Icheon-si (KR); Myung Kyu Ahn, Icheon-si (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Kyoungki-do (KR)

(21) Appl. No.: 11/478,794

(22) Filed: Jun. 30, 2006

(30) Foreign Application Priority Data
Feb. 7, 2006 (KR) 2006-11549
Feb. 7, 2006 (KR) 2006-11551

(51) Int. Cl. H01L 31/112; H01L 29/80

(52) U.S. Cl. 257/257; 257/E29.3

(57) ABSTRACT

A method of manufacturing a flash memory device, one embodiment of which includes the steps of forming a floating gate pattern in which a tunnel oxide film, a first conductive layer, and a nitride film are laminated on a semiconductor substrate of a first region, and forming isolation films on the semiconductor substrate of a second region; stripping the nitride film and then etching the isolation films to a predetermined thickness by a dry etch process; and, sequentially forming a dielectric film, a second conductive layer, and a hard mask film on the entire structure, patterning the hard mask film to form a control gate, and etching the floating gate pattern using the control gate as a mask, thus forming a floating gate. After the nitride film serving as the etch mask for forming the trenches is stripped, the etch process of the isolation films for controlling an EFH is performed under the conditions in which the isolation films are etched while the conductive layer is not etched. Accordingly, damage to lateral and upper portions of the conductive layer for the floating gate can be prevented, the occurrence of moat at the peri region can be prevented, and the reliability of devices can be improved accordingly.

### BACKGROUND

1. Field of the Invention

The invention relates generally relates to semiconductor memory devices. More particularly, the invention relates to a method of manufacturing a flash memory device, which can protect damage to lateral and upper portions of a conductive layer for a floating gate in an etch process of an isolation film for controlling an effective field height (EFH) and can prevent moat formation at a peri region.

2. Discussion of Related Art

A NAND flash memory device performs data programming by injecting electrons into the floating gate by Fowler-Nordheim (FN) tunneling, thereby proving a large capacity and a high degree of integration.

The NAND flash memory device includes a plurality of cell blocks. One cell block includes a plurality of cell strings in which a plurality of cells for storing data are connected in series to form one string, and a drain select transistor and a source select transistor formed between the cell string and the drain, and the cell string and the source, respectively. Each cell block further includes a peri region in which a plurality of circuit elements for generating predetermined biases for the program, erase, and read operations of the cells and transferring the biases are formed.

The NAND flash memory cell is formed by forming an isolation film on a semiconductor substrate, forming a gate in which a tunnel oxide film, a floating gate, a dielectric film and a control gate are laminated on the semiconductor substrate, and forming junctions on both sides of the gate.

In the manufacturing process of NAND flash memory devices of 60 nm or less, however, in order to prevent a thinning phenomenon of a tunnel oxide film while securing an overlap margin of a floating gate and an active region, a method of forming a conductive layer for the floating gate and performing a trench etch process for forming an isolation film simultaneously with the etch process of the conductive layer is employed. In this case, however, in order to increase the contact area of the dielectric film and the floating gate, a process of controlling the EFH by etching the isolation film at a predetermined depth has been performed.

Meanwhile, in devices of 60 nm or less, since a trench and a floating gate pattern are formed at the same time, an active region is exposed and damaged in an etch process of forming a control gate. To prevent the problem, a dual EFH structure in which the EFH of the peri region is set higher than that of the cell region is employed. To this end, after a photoresist film is formed only in the peri region, the etch process of the isolation film of the cell region is performed.

However, the etch process of the isolation film for controlling the EFH employs a wet etch process. Accordingly, the sides of the conductive layer for the floating gate, which are exposed by etching the isolation film, are damaged. Furthermore, a nitride film is used as a hard mask for etching the trench. The nitride film is stripped by a wet etch process using phosphoric acid (H₃PO₄) by etching the isolation film at a predetermined thickness and then stripping the photoresist film formed in the peri region. However, when the nitride film is stripped, a part of a top surface of the conductive layer for the floating gate of the cell region is damaged. In addition, after the nitride film is stripped, the isolation film is etched using HF in order to finally control the EFH. HF has a property that the conductive layer is rarely etched while the isolation film is etched. Accordingly, while the isolation film of the peri region is etched isotropically, a moat is generated between the isolation film and the conductive layer.

Such damage to the conductive layer for the floating gate, which is generated when the isolation film is etched and the nitride film is stripped, not only leads to damage to the active region when the gate is etched subsequently, but also cause a serious problem in the data storage function of the floating gate because the volume of the floating gate is reduced.

In other words, such a reduction in the volume of the floating gate may lead to not only a reduced storage capacity, but also to an irregular thickness of the dielectric film formed on the damaged floating gate. As a result, a threshold voltage can be varied and stored electrons can be leaked, giving a deathblow to device operation.

### SUMMARY OF THE INVENTION

In one embodiment, the invention provides a method of manufacturing a flash memory device, which can prevent damage to lateral and upper portions of a conductive layer for a floating gate when a nitride film and an isolation film are etched.

In another embodiment, the invention provides a method of manufacturing a flash memory device, which can prevent damage to lateral and upper portions of a conductive layer for a floating gate by performing a dry etch process in such a manner that only an isolation film is etched while not etching the conductive layer in the etch process of the isolation film for controlling the EFH after a nitride film is etched.

In a further embodiment, the invention provides a method of manufacturing a flash memory device, which can prevent the occurrence of a most between an isolation film and a conductive layer of a peri region in the process of finally controlling the EFH.

According to one aspect, the invention provides a method of manufacturing a flash memory device, including the steps of forming a floating gate pattern in which a tunnel oxide film, a first conductive layer, and a nitride film are laminated on a semiconductor substrate of a first region, and forming isolation films on the semiconductor substrate of a second region; stripping the nitride film and then etching the isolation films to a predetermined thickness by a dry etch process; and sequentially forming a dielectric film, a second conductive layer, and a hard mask film on the entire structure, patterning the hard mask film to form a control gate, and etching the floating gate pattern using the control gate as a mask, thus forming a floating gate.

The method may further include the step of stripping the isolation films to a thickness, which equals to a thickness of the nitride film before the nitride film is stripped.

The dry etch process may preferably be performed under the conditions in which only the isolation films are etched while not etching the first conductive layer.

The dry etch process may preferably be performed using a mixed gas of CF₄ and/or CHF₃.

The dry etch process may preferably be performed using ICP type equipment or MERIE equipment.

The dry etch process using the ICP type equipment may preferably be performed by applying a pressure of 3 mTorr to 100 mTorr and source and bias powers of 500 W to 1000 W.

The dry etch process using the MERIE equipment may preferably be performed by applying a pressure of 10 mTorr to 200 mTorr and source and bias powers of 100 W to 1000 W.

The method may optionally further include the step of performing a cleaning process before the dielectric film is formed whereby the isolation films are etched to a predetermined thickness.

The hard mask film may preferably be formed by an oxide film, amorphous carbon or the like.

According to another aspect, the invention provides a method of manufacturing a flash memory device, including the steps of providing a semiconductor substrate in which a cell region and a peri region are defined; forming a floating gate pattern in which a tunnel oxide film, a first conductive layer, and a nitride film are laminated on the semiconductor substrate of a first region, and forming isolation films on the semiconductor substrate of a second region; stripping the nitride film, blocking the peri region, and then etching the isolation films of the cell region to a predetermined thickness by a dry etch process; and sequentially forming a dielectric film, a second conductive layer, and a hard mask film on the entire structure, patterning the hard mask film to form a control gate, and etching the floating gate pattern using the control gate as a mask, thus forming a floating gate.

The method may optionally further include the step of stripping the isolation films to a thickness, which equals to a thickness of the nitride film before the nitride film is stripped.

The dry etch process may preferably be performed under the conditions in which only the isolation films are etched while not etching the first conductive layer.

The dry etch process may preferably be performed using a mixed gas of CF₄ and/or CHF₃.

The dry etch process may preferably be performed using ICP type equipment or MERIE equipment.

The dry etch process using the ICP type equipment may preferably be performed by applying a pressure of 3 mTorr to 100 mTorr and source and bias powers of 500 W to 1000 W.

The dry etch process using the MERIE equipment may preferably be performed by applying a pressure of 10 mTorr to 200 mTorr and source and bias powers of 100 W to 1000 W.

The method may optionally further include the step of etching the isolation films of the cell region and the peri region to a predetermined thickness after the isolation films of the cell region are etched.

The hard mask film may preferably be formed by an oxide film, amorphous carbon or the like.

According to a further aspect, the invention provides a method of manufacturing a flash memory device, including the steps of providing a semiconductor substrate in which a cell region and a peri region are defined; sequentially laminating a tunnel oxide film, a first conductive layer, and a nitride film on the semiconductor substrate of a first region and forming isolation films the semiconductor substrate of a second region; stripping the nitride film, blocking the peri region, and then etching the isolation films of the cell region to a predetermined thickness by a dry etch process; forming second conductive layer on the first conductive layer in such a way to be partially overlapped with the isolation films, forming a floating gate pattern; and sequentially forming a dielectric film, a second conductive layer, and a hard mask film on the entire structure, patterning the hard mask film to form a control gate, and etching the floating gate pattern using the control gate as a mask, thus forming a floating gate.

### BRIEF DESCRIPTION OF THE DRAWINGS

A more compete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIGS. 1A to 1D are cross-sectional views illustrating a method of manufacturing a flash memory device according to an embodiment of the invention; and

FIGS. 2A to 2E are cross-sectional views illustrating a method of manufacturing a flash memory device according to another embodiment of the invention.

### DETAILED DESCRIPTION OF EMBODIMENTS

The invention is described in detail below in connection with certain exemplary embodiments with reference to the accompanying drawings.

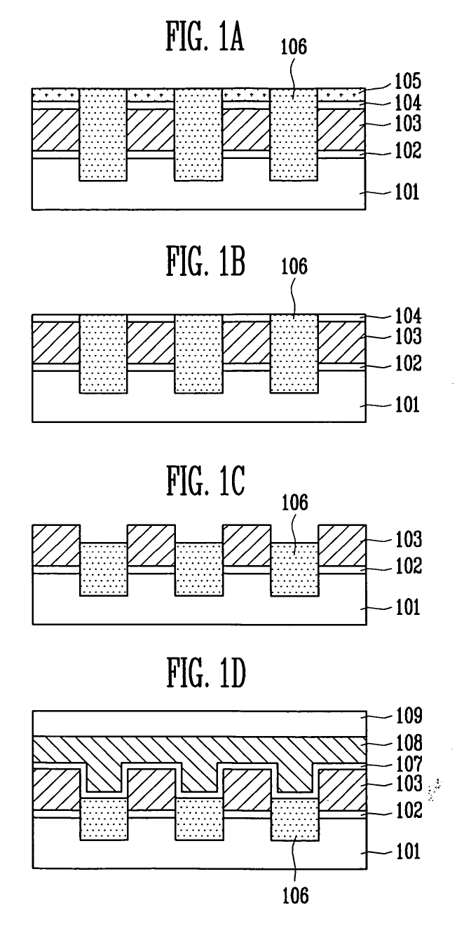

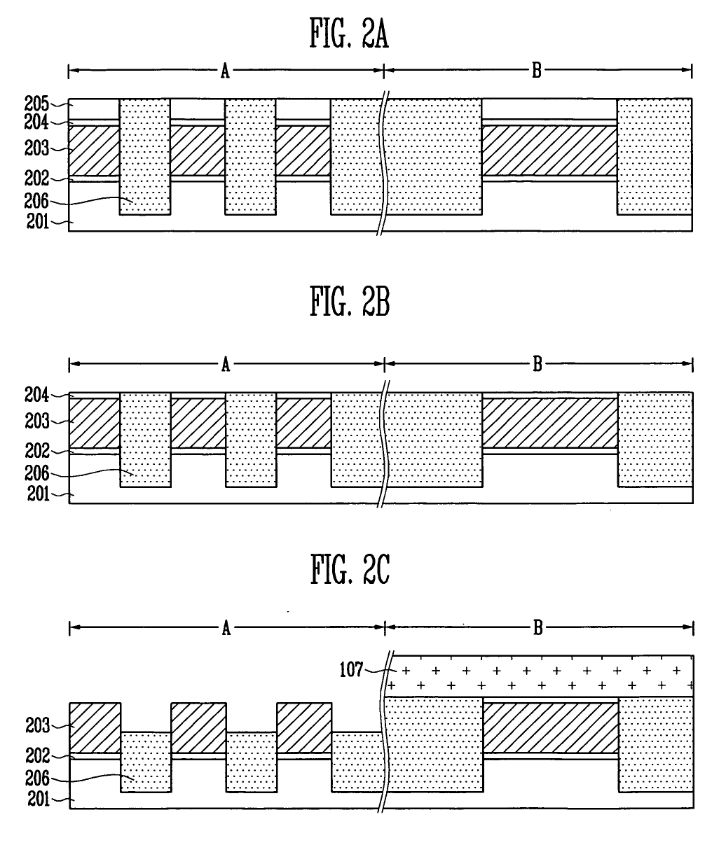

FIGS. 1A to 1D are cross-sectional views illustrating a method of manufacturing a flash memory device according to an embodiment of the invention. Referring to FIG. 1a, a tunnel oxide film 102, a first conductive layer 103, a buffer oxide film 104, and a nitride film 105 are sequentially formed on a semiconductor substrate 101. The first conductive layer 103 may be formed to a thickness of 500 Å to 2000 Å using a polysilicon film. It is preferred that the first conductive layer 103 be formed by laminating an undoped polysilicon film and a doped polysilicon film.

To define an active region and a field region, the nitride film 105 is patterned by photolithography and etch processes using an isolation mask. The buffer oxide film 104, the first conductive layer 103, the tunnel oxide film 102, and a predetermined portion of the semiconductor substrate 101 are sequentially etched using the patterned nitride film 105 as an etch mask, thus forming trenches. The trenches are formed in the field region and the active region and the field region are defined in parallel. In the active region, the first conductive layer 103 is patterned and the floating gate pattern is defined.

After an insulating film is formed on the entire structure so that the trenches are buried, a chemical mechanical polishing (CMP) process is performed to form isolation films 106 so that the nitride film 106. The isolation films 106 may be formed using a high density plasma (HDP) oxide film or may be formed by laminating a HDP oxide film and a SOD film.

Referring to FIG. 1B, after the isolation films 106 are partially etched, the nitride film 105 is stripped by a wet etch process, preferably using phosphoric acid (H₃PO₄). The isolation films 106 is etched to the same thickness of that of the nitride film 105 so that the isolation films 106 have almost the same height as that of the buffer oxide film 104 after the nitride film 105 is etched. The buffer oxide film 104 serves to protect the first conductive layer 103 when the nitride film 105 is stripped.

Referring to FIG. 1C, the isolation films 106 are etched to a predetermined thickness by a dry etch process under the conditions that only the isolation films 106 are etched while the first conductive layer 103 is not etched. Accordingly, the EFH of the isolation films 106 can be controlled. At this time, when the isolation films 106 are etched, the buffer oxide film 104 is also etched. The etch process of the isolation films 106 may be performed using a mixed gas of CF₄ and/or CHF₃. It is preferred that the etch process be performed using a mixed gas of CF₄, CHF₃, Ar, and oxygen (O₂). The Argon gas is introduced by a small amount of about 0 sccm to 50 sccm.

Meanwhile, the etch process of the isolation films 106 may be performed using an inductively couple plasma (ICP) type equipment or a magnetically enhanced reactive ion etch (MERIE) equipment. When the ICP type equipment is used, the etch process is preferably performed using a pressure of 3 mTorr to 100 mTorr and source and bias power of 500 W to 1000 W. When the MERIE equipment is used, the etch process is preferably performed using a pressure of 10 mTorr to 200 mTorr and source and bias power of 100 W to 1000 W.

More particularly, the oxide film etch chamber of a MERIE type can secure a high etch selectivity against the conductive layer compared with other etch chambers and can minimize a collision effect of ions when a low bias is used. Accordingly, a top surface of the first conductive layer 103 can be prevented from being damaged by sputtering.

Referring to FIG. 1D, a dielectric film 107, a second conductive layer 108, and a hard mask film 109 are sequentially formed on the entire structure. The dielectric film 107 may be formed using a film of an ONO structure or a high dielectric film. For example, the high dielectric material may include materials, such as Al₂O₃, HfO₂, ZrO₂, SiON, La₂O₃, Y₂O₃, TiO₂, CeO₂, N₂O₃, Ta₂O₅, BaTiO₃, SrTiO₃, BST, and PZT, and mixed oxide, such as HfxAlyOz, ZrxAlyOz, HfSiO₄, and ZrSiO₄.

Meanwhile, the second conductive layer 107 may be formed using a single layer of a polysilicon film or a lamination structure of a polysilicon film and a tungsten silicide film. Furthermore, the hard mask film 109 may be formed using an oxide film, amorphous carbon or the like.

After the hard mask film 109 is patterned by photolithography and etch processes using a control gate mask, the second conductive layer 108 is etched to form a control gate vertical to the isolation films 106. Regions from the dielectric film 107 to a predetermined region of the tunnel oxide film 102 are etched by a continuous etch process, thereby forming a floating gate.

Meanwhile, in the above embodiment, the process of forming the conductive layer for the floating gate using a single layer has been described. However, the invention is not limited thereto, but may be applied to other processes in which the isolation films of a region exposed when the control gate and the floating gate are formed are etched to expose the lateral portions of the semiconductor substrate. For example, the invention may be applied to a so-called self-aligned shallow trench isolation (SA-STI) process in which the floating gate is formed using the lamination structure of the first and second conductive layers. The SA-STI process will be described in short below.

A tunnel oxide film, a first conductive layer, a buffer oxide film, and a nitride film are sequentially formed on a semiconductor substrate. Predetermined regions of the tunnel oxide film, the first conductive layer, the buffer oxide film, and the nitride film, and a predetermined depth of the semiconductor substrate are etched to form trenches. The trenches are buried to form isolation films. The isolation film are etched at a predetermined thickness and the nitride film is stripped. A process of etching the isolation films in order to control the EFH is performed using a dry etch process under the conditions in which the etch selectivity against the first conductive layer is good. A second conductive layer is formed so that it is overlapped with the isolation films, thus forming a floating gate pattern having the first and second conductive layers. Subsequent processes are the same as those described with reference to the drawings. In this case, the first conductive layer may preferably be formed to a thickness of 100 Å to 1000 Å and the second conductive layer may preferably be formed to a thickness of 200 Å to 1500 Å.

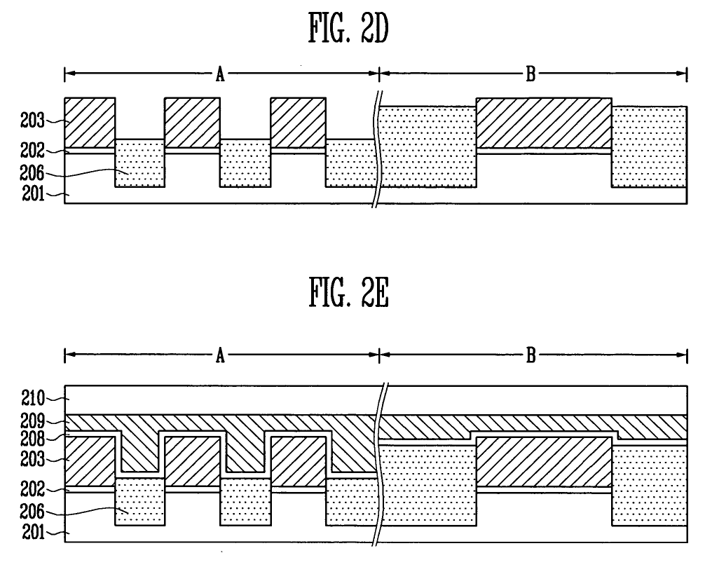

FIGS. 2A to 2E are cross-sectional views illustrating a method of manufacturing a flash memory device according to another embodiment of the invention.

Referring to FIG. 2A, a tunnel oxide film 202, a first conductive layer 203, a buffer oxide film 204, and a nitride film 205 are sequentially formed on a semiconductor substrate 201 in which a cell region A and a peri region B are defined. The first conductive layer 203 may preferably be formed to a thickness of 500 Å to 2000 Å using a polysilicon film. It is preferred that the first conductive layer 203 be formed by laminating an undoped polysilicon film and a doped polysilicon film.

The nitride film 205 is patterned by photolithography and etch processes using an isolation mask in order to define an active region and a field region. The buffer oxide film 204, the first conductive layer 203, the tunnel oxide film 202, and a predetermined portion of the semiconductor substrate 201 are sequentially etched using the patterned nitride film 205 as an etch mask, thus forming trenches. The trenches have a width wider in the peri region B than in the cell region A. The active region and the field region are defined in parallel by means of the trenches. In the active region, the first conductive layer 203 is patterned and a floating gate pattern is defined accordingly.

After an insulating film is formed on the entire structure so that the trenches are buried, a CMP process is performed so that the nitride film 206 is exposed, thereby forming isolation films 206. The isolation films 206 may be formed using a HDP oxide film or may be formed by laminating a HDP oxide film and a spin on dielectrics (SOD) film.

Referring to FIG. 2B, after the isolation films 206 are partially etched by a wet etch process using buffered oxide etchant (BOE), the nitride film 205 is stripped by a wet etch process using phosphoric acid (H₃PO₄). The isolation films 206 is etched to the same thickness of that of the nitride film 205 so that the isolation films 206 have almost the same height as that of the buffer oxide film 204 after the nitride film 205 is etched. The buffer oxide film 204 serves to protect the first conductive layer 203 when the nitride film 205 is stripped.

Referring to FIG. 2C, after a photoresist film 207 is formed on the entire structure, exposure and development processes using a peri region-blocking mask are performed so that the photoresist film 207 remains only in the peri region B. The EFH of the isolation films 206 is controlled by etching the isolation films 206 to a predetermined thickness by means of a dry etch process under the conditions that only the isolation films 206 are etched while the first conductive layer 203 is not etched with the photoresist film 207 being left in the peri region B. At this time, when the isolation films 206 are etched, the buffer oxide film 204 is also etched. The dry etch process for etching the isolation films 206 may preferably be performed using a mixed gas of CF₄ and/or CHF₃, preferably a mixed gas of CF₄, CHF₃, Ar, and oxygen (O₂). The Argon gas is introduced by a small amount of about 0 sccm to 50 sccm.

Meanwhile, the etch process of the isolation films 206 may be performed using ICP type equipment or MERIE equipment. When the ICP type equipment is used, the etch process is preferably performed using a pressure of 20 mTorr to 100 mTorr and source and bias power of 500 W to 1000 W. When the MERIE equipment is used, the etch process is performed using a pressure of 10 mTorr to 200 mTorr, a source power of 100 W to 500 W, and a bias power of 100 W to 1000 W.

More particularly, when the ICP type equipment is used, a low source power and a high bias power is applied so that polymer can be formed while minimizing the concentration of fluorine atoms in order to minimize damage to the top surface of the first conductive layer 203 by the fluorine atoms. By dry-etching the isolation films 206 using the above-mentioned conditions, top corners of the first conductive layer 203 of the cell region A can be rounded. If the top corners of the first conductive layer 203 are rounded, electric field is not concentrated on the corners and a subsequent dielectric film can be deposited uniformly.

Referring to FIG. 2D, the photoresist film 207 and the buffer oxide film 204 formed in the peri region B are stripped. A final EFH is controlled by etching the isolation films 206 of the cell region A and the peri region B to a predetermined thickness by a wet cleaning process using HF. In this case, since the isolation films 206 are etched to a predetermined thickness before the nitride film 205 is stripped, an etch process time of the isolation films 206 for controlling the EFH and a process time for controlling the final EFH can be shortened. Accordingly, damage to the first conductive layer 203 of the cell region A and the occurrence of moat at the peri region B can be prevented.

Referring to FIG. 2E, a dielectric film 207, a second conductive layer 208, and a hard mask film 210 are sequentially formed on the entire structure. The dielectric film 207 may be formed using a film of an ONO structure or a high dielectric film. For example, the high dielectric material may include materials, such as Al₂O₃, HfO₂, ZrO₂, SiON, La₂O₃, Y₂O₃, TiO₂, CeO₂, N₂O₃, Ta₂O₅, BaTiO₃, SrTiO₃, BST, and PZT, and mixed oxide, such as HfxAlyOz, ZrxAlyOz, HfSiO₄, and ZrSiO₄. Meanwhile, the second conductive layer 207 may be formed using a single layer of a polysilicon film or a lamination structure of a polysilicon film and a tungsten silicide film. Furthermore, the hard mask film 210 may be formed using an oxide film, amorphous carbon or the like.

After the hard mask film 210 is patterned by photolithography and etch processes using a control gate mask, the second conductive layer 208 is etched to form a control gate vertical to the isolation films 206. Regions from the dielectric film 207 to a predetermined region of the tunnel oxide film 202 are etched by a continued etch process, thereby forming a floating gate.

Meanwhile, in the above embodiment, the process of forming the conductive layer for the floating gate using a single layer has been described. However, the invention is not limited thereto, but may be applied to other processes in which the isolation films of a region exposed when the control gate and the floating gate are formed are etched to expose the lateral portions of the semiconductor substrate. For example, the invention may be applied to a so-called SA-STI process in which the floating gate is formed using the lamination structure of the first and second conductive layers. The SA-STI process will be described in short below.

A tunnel oxide film, a first conductive layer, a buffer oxide film, and a nitride film are sequentially formed on a semiconductor substrate in which a cell region and a peri circuit are defined. Predetermined regions of the tunnel oxide film, the first conductive layer, the buffer oxide film, and the nitride film, and a predetermined depth of the semiconductor substrate are etched to form trenches. The trenches are buried to form isolation films. The isolation films are etched to a predetermined thickness and the nitride film is stripped. After a photoresist film is formed only in the peri region, a process of etching the isolation films of the cell region in order to control the EFH is performed using a dry etch process under the conditions in which the isolation films are etched while the first conductive layer is not etched.

After the photoresist film and the buffer oxide film of the peri region are stripped, a cleaning process is performed to control a final EFH. A second conductive layer is formed so that it is overlapped with the isolation films, thus forming a floating gate pattern having the first and second conductive layers. Subsequent processes are the same as those described with reference to the drawings. In this case, the first conductive layer may preferably be formed to a thickness of 100 Å to 1000 Å and the second conductive layer may preferably be formed to a thickness of 200 Å to 1500 Å.

As described above, according to the invention, after the nitride film serving as the etch mask for forming the trenches is stripped, the etch process of the isolation films for controlling the EFH is performed under the conditions in which the isolation films are etched while the conductive layer is not etched. Accordingly, damage to lateral and upper portions of the conductive layer for the floating gate can be prevented, the occurrence of moat at the peri region can be prevented, and the reliability of devices can be improved accordingly.

While the invention has been described in connection with practical exemplary embodiments, the invention is not limited to the disclosed embodiments but, to the contrary, is intended to cover various modifications and equivalent arrangements included within the spirit and scope of the appended claims.

What is claimed is:

1. A method of manufacturing a flash memory device, comprising the steps of:
forming a floating gate pattern by laminating a tunnel oxide film, a first conductive layer, and a nitride film on a semiconductor substrate of a first region, and forming isolation films on the semiconductor substrate of a second region;
stripping the nitride film and then etching the isolation films to a predetermined thickness by a dry etch process; and
sequentially forming a dielectric film, a second conductive layer, and a hard mask film on the entire structure, patterning the hard mask film to form a control gate, and etching the floating gate pattern using the control gate as a mask, thus forming a floating gate.

2. The method of claim 1, further comprising the step of stripping the isolation films to a thickness, which equals to a thickness of the nitride film before the nitride film is stripped.

3. The method of claim 1, comprising performing the dry etch process under conditions in which only the isolation films are etched while not etching the first conductive layer.

4. The method of claim 1, wherein the dry etch process is performed using a mixed gas of at least one of CF₄ and/or CHF₃.

5. The method of claim 1, comprising performing the dry etch process using ICP type equipment or MERIE equipment.

6. The method of claim 5, comprising performing the dry etch process using ICP type equipment by applying a pressure of 3 mTorr to 100 mTorr and source and bias powers of 500 W to 1000 W.

7. The method of claim 5, comprising performing the dry etch process using MERIE equipment by applying a pressure of 10 mTorr to 200 mTorr and source and bias powers of 100 W to 1000 W.

8. The method of claim 1, further comprising the step of performing a cleaning process before forming the dielectric film whereby the isolation films are etched to a predetermined thickness.

9. The method of claim 1, comprising forming the hard mask film by an oxide film or amorphous carbon.

10. A method of manufacturing a flash memory device, comprising the steps of:
providing a semiconductor substrate in which a cell region and a peri region are defined;
forming a floating gate pattern by laminating a tunnel oxide film, a first conductive layer, and a nitride film on the semiconductor substrate of a first region, and forming isolation films on the semiconductor substrate of a second region;
stripping the nitride film, blocking the peri region, and then etching the isolation films of the cell region to a predetermined thickness by a dry etch process; and
sequentially forming a dielectric film, a second conductive layer, and a hard mask film on the entire structure, patterning the hard mask film to form a control gate, and etching the floating gate pattern using the control gate as a mask, thus forming a floating gate.

11. The method of claim 10, further comprising the step of stripping the isolation films to a thickness, which equals to a thickness of the nitride film before the nitride film is stripped.

12. The method of claim 10, comprising performing the dry etch process under conditions in which only the isolation films are etched while not etching the first conductive layer.

13. The method of claim 10, comprising performing the dry etch process using a mixed gas of at least one of CF₄ and CHF₃.

14. The method of claim 10, comprising performing the dry etch process using ICP type equipment or MERIE equipment.

15. The method of claim 14, comprising performing the dry etch process using ICP type equipment by applying a pressure of 3 mTorr to 100 mTorr and source and bias powers of 500 W to 1000 W.

16. The method of claim 14, comprising performing the dry etch process using MERIE equipment by applying a pressure of 10 mTorr to 200 mTorr and source and bias powers of 100 W to 1000 W.

17. The method of claim 10, further comprising the step of etching the isolation films of the cell region and the peri region to a predetermined thickness after the isolation films of the cell region are etched.

18. The method of claim 10, comprising forming the hard mask film by an oxide film or amorphous carbon.

19. A method of manufacturing a flash memory device, comprising the steps of:
providing a semiconductor substrate in which a cell region and a peri region are defined;
sequentially laminating a tunnel oxide film, a first conductive layer, and a nitride film on the semiconductor substrate of a first region and forming isolation films the semiconductor substrate of a second region;
stripping the nitride film, blocking the peri region, and then etching the isolation films of the cell region to a predetermined thickness by a dry etch process;
forming second conductive layer on the first conductive layer in such a way to be partially overlapped with the isolation films, forming a floating gate pattern; and
sequentially forming a dielectric film, a second conductive layer, and a hard mask film on the entire structure, patterning the hard mask film to form a control gate, and etching the floating gate pattern using the control gate as a mask, thus forming a floating gate.
